(19) United States
(12) Patent Application Publication
(10) Pub. No.: US 2023/0407051 A1
(43) Pub. Date: Dec. 21, 2023

(54) PROCESS OF FORMING SILICON-CONTAINING FILM AND METHOD OF MANUFACTURING INTEGRATED CIRCUIT DEVICE USING THE SAME

(71) Applicant: SAMSUNG ELECTRONICS CO., LTD., Suwon-si (KR)

(72) Inventors: Jihyun LEE, Suwon-si (KR); Sunggi KIM, Daedeok-gu (KR); Yujin CHO, Daedeok-gu (KR); Sunhye HWANG, Suwon-si (KR); Seung SON, Daedeok-gu (KR); Gyunsang LEE, Daedeok-gu (KR); Younjoung CHO, Suwon-si (KR); Byungkeun HWANG, Suwon-si (KR)

(73) Assignee: DNF Co., Ltd., Daejeon (KR)

(21) Appl. No.: 18/206,187

(22) Filed: Jun. 6, 2023

(30) Foreign Application Priority Data
Jun. 17, 2022 (KR) 10-2022-0074338

(51) Int. Cl. C08K 5/5435; C23C 16/40; C23C 16/453; H01L 27/088; H01L 21/8234

(52) U.S. Cl. CPC C08K 5/5435; C23C 16/401; C23C 16/453; H01L 27/088; H01L 21/8234

(57) ABSTRACT

A silicon compound, a composition for depositing a silicon-containing film, a process of forming a silicon-containing film, and a method of manufacturing an integrated circuit device, the silicon compound is represented by Chemical Formula (1):

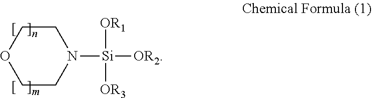

### CROSS-REFERENCE TO RELATED APPLICATION

This application is based on and claims priority under 35 U.S.C. § 119 to Korean Patent Application No. 10-2022-0074338, filed on Jun. 17, 2022, in the Korean Intellectual Property Office, the disclosure of which is incorporated by reference herein in its entirety.

### BACKGROUND

### 1. Field

Embodiments relate to a process of forming a silicon-containing film, and a method of manufacturing an integrated circuit device using the same.

### 2. Description of the Related Art

With the recent development of electronics technology, ultra-miniaturization of integrated circuit devices has been rapidly conducted. Accordingly, the size of a device area has been reduced and the aspect ratio of unit devices has been increased, and thus, a silicon containing film may be formed having a uniform thickness and excellent electrical properties.

### SUMMARY

The embodiments may be realized by providing a silicon compound represented by Chemical Formula (1):

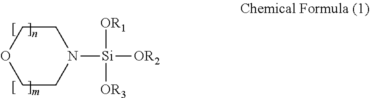

wherein, in Chemical Formula (1), R₁ to R₃ are each independently a C1-C4 alkyl group, and n and m are each independently an integer of 0 to 3.

The embodiments may be realized by providing a composition for depositing a silicon-containing film, the composition comprising the silicon compound according to an embodiment.

The embodiments may be realized by providing a process of forming a silicon-containing film, the process including forming a silicon compound adsorption layer on a substrate having a temperature of 550° C. or more, by supplying a silicon compound represented by Chemical Formula (1); and supplying a reaction gas onto the silicon compound adsorption layer,

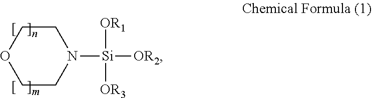

wherein, in Chemical Formula (1), R₁ to R₃ are each independently a C1-C4 alkyl group, and n and m are each independently an integer of 0 to 3.

The embodiments may be realized by providing a method of manufacturing an integrated circuit device, the method including forming a silicon oxide film on a substrate having a temperature of 550° C. or more, by using a silicon compound represented by Chemical Formula (1):

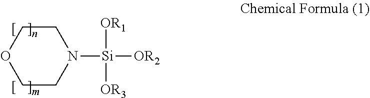

wherein, in Chemical Formula (1), R₁ to R₃ are each independently a C1-C4 alkyl group, and n and m are each independently an integer of 0 to 3.

The embodiments may be realized by providing a method of manufacturing an integrated circuit device, the method including preparing a substrate having an active area and a device separation area; forming a gate dielectric film on the substrate; forming a gate electrode on the gate dielectric film; forming a gate structure by patterning the gate dielectric film and the gate electrode; and forming a source/drain region formed in the substrate at both sides of the gate structure, wherein forming the gate dielectric film includes forming a silicon compound adsorption layer on a surface of the substrate by supplying a silicon compound represented by Chemical Formula (1) onto the substrate having a temperature of 550° C. or more; and forming a silicon oxide film by supplying a reaction gas to the silicon compound adsorption layer,

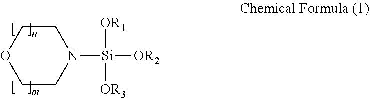

in Chemical Formula (1), R₁ to R₃ are each independently a C1-C4 alkyl group, and n and m are each independently an integer of 0 to 3.

### BRIEF DESCRIPTION OF THE DRAWINGS

Features will be apparent to those of skill in the art by describing in detail exemplary embodiments with reference to the attached drawings in which:

FIG. 1 is a flowchart showing a method of manufacturing an integrated circuit device, according to an embodiment;

FIG. 2 is a flowchart showing in detail a method of forming a silicon containing film according to a method of manufacturing an integrated circuit device, according to an embodiment;

FIGS. 3 to 6 are views showing an integrated circuit device including a silicon containing film manufactured according to the method of manufacturing an integrated circuit device, according to an embodiment;

FIG. 7 is a graph showing thermogravimetric analysis result with respect to each of a Synthesis Example and a Comparative Example;

FIG. 8 is a graph showing a differential scanning calorimetry (DSC) analysis result with respect to each of a Synthesis Example and a Comparative Example; and

FIG. 9 is a graph showing a vapor pressure measurement result with respect to each of a Synthesis Example and a Comparative Example.

### DETAILED DESCRIPTION

In the specification, the term “substrate” used herein may mean a substrate by itself, or a stack structure including a substrate and a certain layer or film formed on a surface thereof.

In the specification, the term “surface of a substrate” used herein may mean an exposed surface of a substrate by itself, or an external surface such as a certain layer or film formed on the substrate. In the specification, unless otherwise described, each substitutable group may be substituted or unsubstituted.

In the specification, the term “room temperature” or “ambient temperature” used herein may be about 20° C. to about 28° C., and may vary depending on the season.

In the specification, the term “alkyl” used herein may mean a monovalent straight chain or branched chain saturation hydrocarbon radical composed of carbon and hydrogen atoms. As used herein, the term “or” is not an exclusive term, e.g., “A or B” would include A, B, or A and B.

A silicon compound used as a precursor in a process of forming a silicon-containing film according to an embodiment may be represented by, e.g., Chemical Formula (1) below.

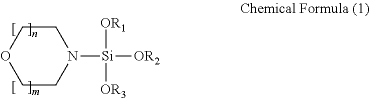

In Chemical Formula (1), R₁ to R₃ may each independently be or include, e.g., a C1-C4 alkyl group. n and m may each independently be, e.g., an integer of 0 to 3.

In an implementation, in the silicon compound of Chemical Formula (1), R₁ to R₃ may each independently be, e.g., a methyl group or an ethyl group, and n and m may each independently be, e.g., an integer of 0 to 2.

In an implementation, the silicon compound of Chemical Formula (1) may have a structure represented by, e.g., Compound (1) below.

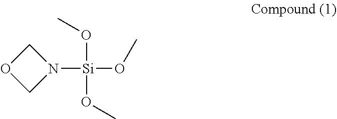

In an implementation, the silicon compound of Chemical Formula (1) may have a structure represented by, e.g., Compound (2) below.

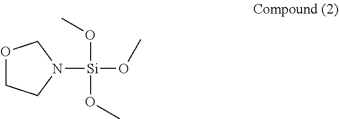

In an implementation, the silicon compound of Chemical Formula (1) may have a structure represented by, e.g., Compound (3) below.

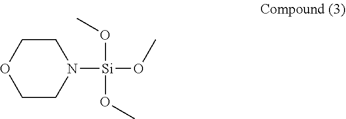

In an implementation, the silicon compound of Chemical Formula (1) may be, e.g., (morpholino)trimethoxysilane.

The silicon compound of Chemical Formula (1) may include a plurality of alkoxy groups. The alkoxy group may include, e.g., a methoxy group, an ethoxy group, a propyl/profileoxy group, an isopropyl/profileoxy group, a butoxy group, an isobutoxy group, an s-butoxy group, or a t-butoxy group.

A silicon compound according to an embodiment may have a relatively high process temperature and relatively high thermal stability, and as a silicon precursor for forming a silicon-containing film, may provide excellent reactivity. The relatively high process temperature may mean that a process temperature of a substrate is 550° C. or more, e.g., 550° C. to 650° C.

In an implementation, when a silicon-containing film is formed by using the silicon compound according to an embodiment, a high purity silicon-containing film that does not include chlorine (Cl) element may be provided. In the case of other silicon-containing films including a Cl element, due to a trap site formed by the Cl element, the degradation potential of time-dependent dielectric film breakdown (TDDB) properties may be very high. In other words, the silicon compound of Chemical Formula (1) may not include Cl, and the above issue may be addressed.

The silicon compound according to an embodiment may be synthesized by applying suitable organic chemical reactions. A detailed description thereof is described below.

The silicon compound according to an embodiment may be used as a raw material suitable for an atomic layer deposition (ALD) process. In an implementation, the silicon compound may be used as, e.g., a precursor suitable for a thermal ALD or plasma enhanced ALD (PEALD) process.

One or more embodiments may provide a composition for depositing a silicon-containing film including the silicon compound, and a process of forming a silicon-containing film using the same.

In an implementation, the silicon compound may be represented by Chemical Formula (1), e.g., Chemical Formula (1), Compound (2), or Compound (3).

The process of forming a silicon-containing film may include forming a silicon compound adsorption layer on a substrate having a temperature of 550° C. or more, by supplying a silicon compound according to an embodiment or a composition for depositing a silicon-containing film including the same, and supplying a reaction gas onto the silicon compound adsorption layer.

One or more embodiments may provide a method of manufacturing an integrated circuit device that includes forming a silicon oxide film on a substrate having a temperature of 550° C. or more, by using the silicon compound of Chemical Formula (1).

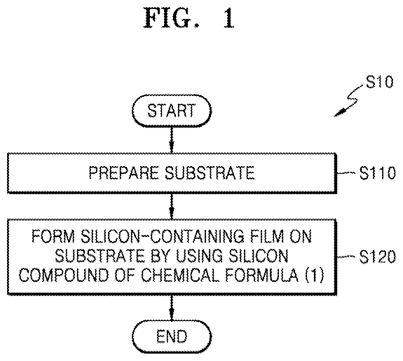

FIG. 1 is a flowchart showing a method of manufacturing an integrated circuit device, according to an embodiment.

Referring to FIG. 1, a method S10 of manufacturing an integrated circuit device may include a process order of first and second operations S110 and S120.

In the first operation S110, a substrate may be prepared. The substrate may include, e.g., a semiconductor substrate, a silicon on insulator (SOI) substrate, quartz, glass, plastic, a metal containing film, an insulating film, or a combination thereof. In an implementation, the semiconductor substrate may include, e.g., Si, Ge, SiGe, GaP, GaAs, SiC, SiGeC, InAs, InP, or a combination thereof. In an implementation, the plastic may include, e.g., polyimide, polyethylene terephthalate, polyethylene naphthalate, poly methyl methacrylate, polycarbonate, polyether sulfone, polyester, or a combination thereof. In an implementation, the metal containing film may include, e.g., Ti, TiN, Ta, TaN, Co, Ru, Zr, Hf, La, W, or a combination thereof.

In the second operation S120, a silicon-containing film may be formed on the substrate by using the composition for forming a silicon-containing film including the silicon compound of Chemical Formula (1).

The composition for forming a silicon-containing film may include a silicon compound according to an embodiment. In an implementation, the composition for forming a silicon-containing film may include a silicon compound represented by Chemical Formula (1) described above.

In an implementation, a silicon-containing film that may be formed according to the method of manufacturing an integrated circuit device, may include, e.g., a silicon oxide (SiO₂) film.

In the second operation S120, an ALD process may be used to form a silicon-containing film. The composition for forming a silicon-containing film including the silicon compound may be used suitable for a chemical deposition process, such as the ALD process.

In an implementation, when the composition for forming a silicon-containing film is introduced into a deposition apparatus, the composition for forming a silicon-containing film may be introduced into a reaction chamber in which a substrate is placed, in a vapor state by vaporization, with a transfer gas, e.g., argon, nitrogen, helium, or the like, used as necessary.

In an implementation, when the composition for forming a silicon-containing film is introduced into a deposition apparatus, the composition for forming a silicon-containing film may be transferred to a vaporization chamber in a liquid or solution state, vaporized to a vapor state in the vaporization chamber by heating and/or decompression, and introduced into the reaction chamber.

In the second operation S120, a process of forming a silicon-containing film may include, e.g., a process of vaporizing a composition for forming a silicon-containing film including the silicon compound of Chemical Formula (1) and introducing the vaporized composition to a reaction chamber where a substrate is placed, and depositing the silicon compound on a surface of the substrate to form a silicon precursor thin film on the substrate; and a process of forming a silicon-containing film on the surface of the substrate by reacting the silicon precursor thin film with a reaction gas.

The reaction gas is a gas reacting with a silicon precursor thin film. In an implementation, the reaction gas may include an oxidizing gas, a reducing gas, or a nitrifying gas. The oxidizing gas may include, e.g., O₂, O₃, O₂ plasma, H₂O, NO₂, NO, nitrous oxide (N₂O), CO, CO₂, H₂O₂, HCOOH, CH₃COOH, (CH₃CO)₂O, alcohol, peroxide, sulfur oxide, or a combination thereof. The reducing gas may include, e.g., hydrogen gas (H₂). The nitrifying gas may include, e.g., NH₃, N₂ plasma, organic amine compounds, such as monoalkylamine, dialkylamine, trialkylamine, alkylenediamine, or the like, a hydrazine compound, or a combination thereof.

In the second operation S120, in the forming of a silicon-containing film, deposition conditions may be controlled according to the thickness of a desired silicon-containing film and the thermal properties of a silicon compound used as a raw material. In an implementation, the deposition conditions may include the input flow rate of a composition for forming a silicon-containing film, the input flow rate of a transfer gas, the input flow rate of a reaction gas, a pressure, a reaction temperature, e.g., a substrate temperature, and the like.

In the second operation S120, in the forming of a silicon-containing film, the thin film thickness of a silicon-containing film may be adjusted by adjusting the number of cycles of an ALD process. The process of forming a silicon-containing film on the substrate by using an ALD process may include, e.g., a process of introducing, into a reaction chamber, vapor obtained by vaporizing a composition for forming a silicon-containing film including a silicon compound; a process of forming a silicon precursor thin film on the surface of the substrate by using the vapor; a process of exhausting an unreacted raw material gas remaining in the reaction space on the substrate; and a process of forming a silicon-containing film on the surface of the substrate by chemically reacting the silicon precursor thin film with a reaction gas.

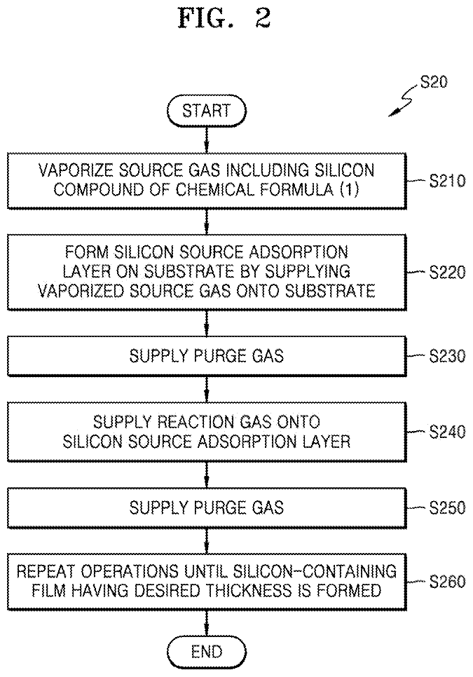

FIG. 2 is a flowchart showing in detail a method of forming a silicon-containing film according to a method of manufacturing an integrated circuit device, according to an embodiment.

Referring to FIG. 2, a method S20 of manufacturing an integrated circuit device may include a process order of first to sixth operations S210 to S260.

In the first operation S210, a source gas including a silicon compound having the structure of Chemical Formula (1) may be vaporized.

In an implementation, the source gas may include the composition for forming a silicon-containing film described above. A process of vaporizing the source gas may be performed at about 180° C. When the source gas is vaporized, the pressure in a raw material container or a vaporization chamber may be, e.g., about 1 Pa to about Pa.

In the second operation S220, a vaporized source gas may be supplied onto the substrate to form a silicon source adsorption layer on the substrate. In an implementation, a reaction temperature may be, e.g., about 550° C. to about 650° C.

By supplying the vaporized source gas onto the substrate, an adsorption layer including a chemisorbed layer and a physisorbed layer of the vaporized source gas may be formed on the substrate. The chemisorbed layer of the vaporized source gas may constitute the silicon source adsorption layer.

In the third operation S230, unnecessary by-products on the substrate may be removed by supplying a purge gas onto the substrate. In an implementation, an inert gas, e.g., Ar, He, Ne, or the like, or nitrogen gas (N₂), or the like may be used as the purge gas.

In an implementation, in lieu of a purge process, exhaustion may be performed by decompressing the reaction space where the substrate is placed. For the decompression, the pressure of the reaction space may be maintained to be, e.g., about Pa to about 300 Pa.

In the fourth operation S240, a silicon-containing film in units of atomic layers may be formed by supplying the reaction gas onto the silicon source adsorption layer formed on the substrate.

In an implementation, when a silicon oxide film is formed on the substrate, the reaction gas may include an oxidizing gas, e.g., O₂, O₃, O₂ plasma, H₂O, NO₂, NO, nitrous oxide (N₂O), CO, CO₂, H₂O₂, HCOOH, CH₃COOH, (CH₃CO)₂O, alcohol, peroxide, sulfur oxide, or a combination thereof. In an implementation, the reaction gas may include a reducing gas, e.g., H₂ gas.

While performing the fourth operation S240, a high temperature state may be maintained so that the silicon source adsorption layer and the reaction gas may sufficiently react with each other. In an implementation, the reaction gas may be plasma-processed. In an implementation, a high frequency (RF) output during the plasma processing may be, e.g., about 0 W to about 1,500 W.

In the fifth operation S250, unnecessary by-products on the substrate may be removed by supplying a purge gas onto the substrate. In an implementation, an inert gas, e.g., Ar, He, Ne, or the like, N₂ gas, or the like may be used as the purge gas.

In the sixth operation S260, until a silicon-containing film having a desired thickness is formed, the first to fifth operations S210 to S250 described above may be repeatedly performed.

In the method S20 of manufacturing an integrated circuit device, as a thin film forming process including a series of processes is set to be one cycle, the cycle may be repeated multiple times until a silicon-containing film having a desired thickness is formed. In an implementation, after performing one cycle, by performing an exhaust process using the purge gas similarly in the third operation S230 or the fifth operation S250, unreacted gases are exhausted from reaction chamber, and then a subsequent cycle may be performed.

In an implementation, the method S20 of manufacturing an integrated circuit device may be variously modified or changed as desired.

In an implementation, to form a silicon-containing film on the substrate, the silicon compound having the structure of Chemical Formula (1) may be supplied onto the substrate together with or sequentially with another precursor, the reaction gas, the transfer gas, or the purge gas. Detailed configurations of other precursor, the reaction gas, the transfer gas, and the purge gas that may be supplied onto the substrate with the silicon compound having the structure of Chemical Formula (1) are described as above.

The silicon-containing film formed by the method may be used as a material for various constituent elements constituting an integrated circuit device. In an implementation, the silicon-containing film may be used as a material forming a gate insulating film constituting a logic device or a memory device. The logic device may include a central processing unit (CPU), a controller, an application specific integrated circuit (ASIC), or the like. The memory device may include volatile memory devices, such as dynamic random access memory (DRAM) or static random access memory (SRAM), or non-volatile memory devices, such as phase-change random access memory (PRAM), magnetoresistive random access memory (MRAM), ferroelectric random access memory (FeRAM), or resistive random access memory (RRAM).

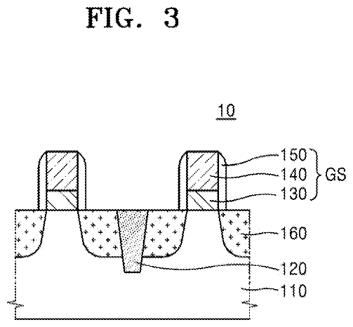

FIGS. 3 to 6 are views showing an integrated circuit device including a silicon-containing film manufactured according to the method of manufacturing an integrated circuit device, according to an embodiment.

Referring to FIG. 3, an integrated circuit device 10 may include a substrate 110, a device separation film 120, a gate structure GS, and a source/drain region 160.

In the integrated circuit device 10 of the present embodiment, the substrate 110 may be substantially the same as that described above with reference to FIG. 1.

The device separation film 120 may be formed as one insulating film, or may include an outer insulating film and an inner insulating film. The outer insulating film and the inner insulating film may be formed of different materials. In an implementation, the outer insulating film may include an oxide film, and the inner insulating film may include a nitride film. An active area may be defined in the substrate 110 by the device separation film 120.

The gate structure GS may include a gate dielectric film 130, a gate electrode 140, and a spacer 150.

The gate dielectric film 130 may be formed by an ALD process by using the silicon compound represented by Chemical Formula (1) described above. In an implementation, the gate dielectric film 130 may have excellent time-dependent dielectric film breakdown properties and high insulating strength properties.

The gate electrode 140 may include one gate film, and may be formed in a multilayer. In an implementation, the gate electrode 140 may include, e.g., an impurity-doped semiconductor, a metal, a conductive metal nitride, or a metal silicide.

The spacer 150 may be formed on side walls of the gate dielectric film 130 and the gate electrode 140. The spacer 150 may include a silicon oxide, a silicon nitride, or a silicon oxynitride. In an implementation, the spacer 150 may be formed in a single layer, or the spacer 150 may be formed in a dual layer or a triple layer.

The source/drain region 160 may be formed in the substrate 110 at both sides of the gate structure GS, and a channel region may be defined below the gate structure GS and between the source/drain region 160.

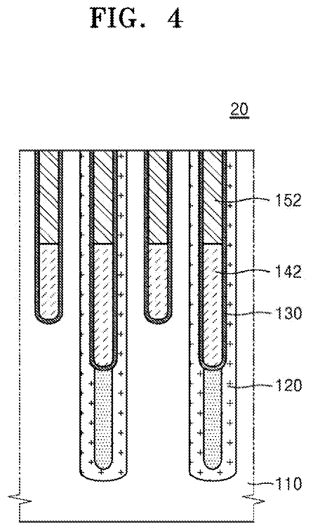

Referring to FIG. 4, an integrated circuit device 20 may include the substrate 110, the device separation film 120, the gate dielectric film 130, a word line 142, and a buried insulating film 152.

In the integrated circuit device 20 of the present embodiment, the substrate 110 and the device separation film 120 may be substantially the same as those described above with reference to FIG. 3. The gate dielectric film 130, the word line 142, and the buried insulating film 152 may be sequentially formed in the active area of the substrate 110.

The gate dielectric film 130 may be formed by an ALD process by using the silicon compound represented by Chemical Formula (1) described above. In an implementation, the gate dielectric film 130 may have excellent time-dependent dielectric film breakdown properties and high insulating strength properties.

The word line 142 may include, e.g., Ti, TiN, Ta, TaN, W, WN, TiSiN, or WSiN.

The buried insulating film 152 may include, e.g., a silicon oxide film, a silicon nitride film, a silicon oxynitride film, or a combination thereof.

A plurality of word lines 142 extending parallel to each other in a first direction may be in the active area of the substrate 110. The word lines 142 may be arranged at regular intervals. The width or interval of the word lines 142 may be determined according to a design rule. A plurality of bit lines extending parallel to each other in a second direction orthogonal to the first direction may be above the word lines 142. The bit lines may also be arranged at regular intervals.

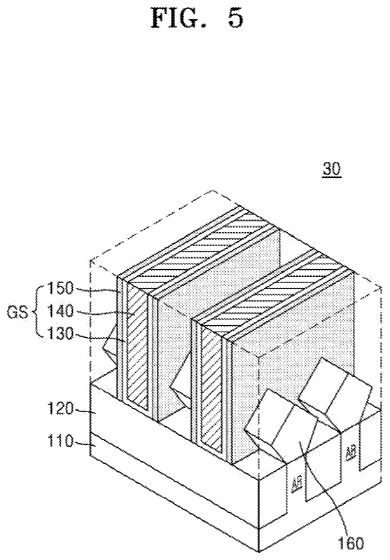

Referring to FIG. 5, an integrated circuit device 30 may include the substrate 110 including a fin-type active area AR, the device separation film 120, the gate dielectric film 130, the gate electrode 140, and the spacer 150.

In the integrated circuit device 30 of the present embodiment, the materials forming the substrate 110 and the device separation film 120 may be substantially the same as those described above with reference to FIG. 3. In an implementation, the integrated circuit device 30 may include a plurality of fin-type active areas AR protruding from the substrate 110 and extending in the first direction. The device separation film 120 may expose an upper area of the fin-type active area AR.

The gate dielectric film 130, the gate electrode 140, and the spacer 150 may be substantially the same as those described above with reference to FIG. 3. The gate dielectric film 130 may be formed by an ALD process by using the silicon compound represented by Chemical Formula (1) described above. In an implementation, the gate dielectric film 130 may have excellent time-dependent dielectric film breakdown properties and high insulating strength properties. The gate structure GS may extend in in the second direction crossing the fin-type active area AR.

The source/drain region 160 may be respectively provided in the fin-type active area AR at both sides of the gate structure GS. The source/drain region 160 may be spaced apart from each other with the gate structure GS therebetween. The source/drain region 160 may include a selective epitaxial growth layer formed by using the fin-type active area AR as a seed.

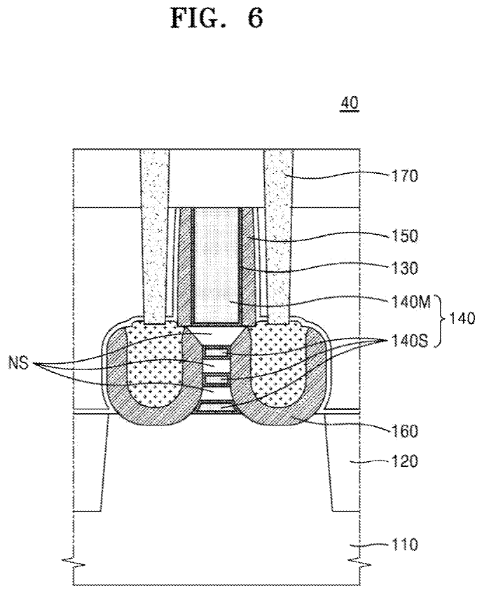

Referring to FIG. 6, an integrated circuit device 40 may include the substrate 110 including a fin-type active area, the device separation film 120, the gate dielectric film 130, the gate electrode 140 including a main gate electrode 140M and a sub-gate electrode 140S, the spacer 150, and a contact structure 170.

In the integrated circuit device 40 of the present embodiment, the materials forming the substrate 110 and the device separation film 120 may be substantially the same as those described above with reference to FIG. 3. In an implementation, the integrated circuit device 40 may include a plurality of fin-type active areas AR protruding from the substrate 110 and extending in the first direction. The device separation film 120 may expose an upper area of the fin-type active area.

A plurality of semiconductor patterns NS may be arranged apart from each other in a direction perpendicular to an upper surface of the substrate 110 in the fin-type active area. The semiconductor patterns NS may have a shape of, e.g., a nanosheet.

The gate electrode 140 may surround the semiconductor patterns NS and may be on the fin-type active area and the device separation film 120. The gate electrode 140 may include the main gate electrode 140M and a plurality of sub-gate electrodes 140S.

The gate dielectric film 130 may be between the gate electrode 140 and the semiconductor patterns NS. The gate dielectric film 130 may be conformally arranged on the upper surface and the side walls of the semiconductor patterns NS. The gate dielectric film 130 may be formed by an ALD process by using the silicon compound represented by Chemical Formula (1) described above. In an implementation, the gate dielectric film 130 may have excellent time-dependent dielectric film breakdown properties and high insulating strength properties.

The source/drain region 160 may include a selective epitaxial growth layer formed by using the fin-type active area as a seed.

As such, the integrated circuit devices 10, 20, 30, and 40 including the silicon-containing film manufactured according to the method of manufacturing an integrated circuit device, according to an embodiment, may be applied in various ways.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

Hereinafter, a formation example of a silicon oxide film and a synthesis example of the silicon compound according to embodiments are described.

In the synthesis examples described below, an ALD process was performed by using atomic layer deposition equipment including a typical vertical furnace.

Furthermore, with respect to a silicon-containing film obtained from a specific formation example described below, a thickness was measured by using an ellipsometer, and thin film properties were analyzed by using an X-ray photoelectron spectroscope.

Furthermore, wet etching resistance of the obtained silicon-containing film was evaluated.

### (1) Synthesis Example

### Synthesis of (morpholino)trimethoxysilane

Under an anhydrous and inactive atmosphere, 286 g (3.28 mol) of morpholine (HN(CH₂)₂(CH₂)₂O) and 1,421 g (19.71 mol) of tetrahydrofuran (C₄H₈O) were added to a flame-dried 4,000 ml flask, and the internal temperature was maintained at −20° C., and after slowly adding 1,227 mL (3.28 mol) of a 2.68 M n-butyllithium (C₄H₉Li) solution thereto, agitated for 5 hours at ambient temperature, thereby manufacturing morpholinelithium salt (C₄H₈LiNO).

The morpholinelithium salt (C₄H₈LiNO) manufactured above was slowly added to a mixed solution of 1,000 mL of hexane (C₆H₁₄) and 500 g (3.28 mol) of tetramethoxysilane ((CH₃O)₄Si), while maintaining a temperature of −20° C. After the addition was complete, the temperature of a reaction solution was slowly increased to ambient temperature, and the solution was agitated for six hours at ambient temperature.

After the reaction was complete, the reaction mixture was filtered to remove lithium salt methanol (LiOCH₃), and a solvent was removed from the obtained solution under reduced pressure, and 450 g (2.17 mol) of (morpholino)trimethoxysilane ((CH₃O)₃SiN(CH₂)₂(CH₂)₂O) was obtained (yield 66%) through decompression distillation in which a temperature of 59° C. was maintained at 0.5 torr.

¹H-NMIR (C₆D₆): δ 3.39 (s, 9H (CH₃O)₃Si), 2.88 (t, 4H, (SiN(CH₂)₂), 3.44 (t, 4H (SiN(CH₂)₂(CH₂)₂O)

²⁹Si-NMR (C₆D₆): δ−67.7 ((CH₃O)₃SiN(CH₂)₂(CH₂)₂O)

Hereinbelow, to evaluate properties of (morpholino)trimethoxysilane according to an embodiment, as a comparison group, bis(pyrrolidino)dimethoxysilane having a chemical structure similar to the synthesis example was selected as a comparative example, and comparisons therebetween were evaluated in various methods.

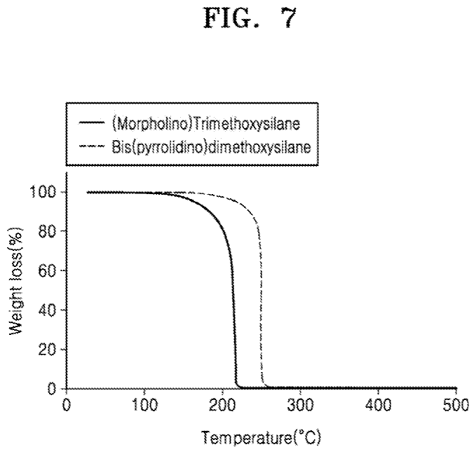

FIG. 7 is a graph showing thermogravimetric analysis result with respect to each of a synthesis example ((morpholino)trimethoxysilane) and a comparative example ((bis(pyrrolidino)dimethoxysilane).

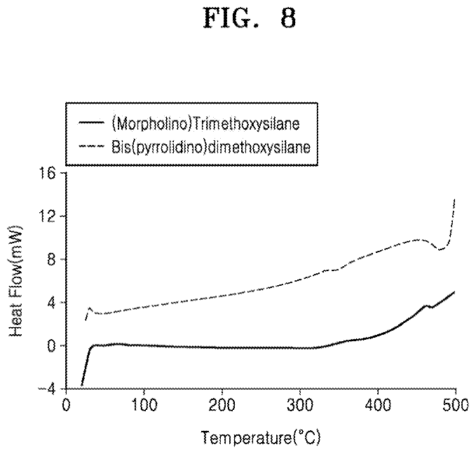

FIG. 8 is a graph showing a differential scanning calorimetry (DSC) analysis result with respect to each of a synthesis example ((morpholino)trimethoxysilane) and a comparative example ((bis(pyrrolidino)dimethoxysilane).

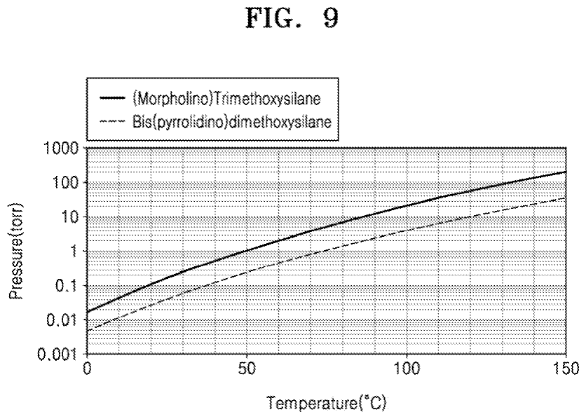

FIG. 9 is a graph showing a vapor pressure measurement result with respect to each of a synthesis example ((morpholino)trimethoxysilane) and a comparative example ((bis(pyrrolidino)dimethoxysilane).

It may be seen from FIGS. 7 to 9 that the synthesis example (morpholino)trimethoxysilane exhibited excellent thermal stability and simultaneously an excellent vapor pressure.

### (2) Formation Example

Deposition of a Silicon Oxide Film by an ALD Process

In an atomic layer deposition apparatus configured as a vertical furnace using an ALD process, a thin film evaluation like an ALD window (550° C. to 650° C.) evaluation was performed by using (morpholino)trimethoxysilane that is the compound of the Synthesis Example, as a composition for depositing a silicon-containing film for forming a silicon oxide film.

As such, a temperature range enabling the ALD process is referred to as an ALD window, and the range of ALD window is dependent on a silicon compound. During an ALD window evaluation, the (e.g., surface) temperature of a substrate was set to be in a range of 550° C. to 650° C., and a silicon precursor was filled in a stainless steel bubbler container and maintained at 80° C.

O₂ gas and H₂ gas were used as reaction gases, and N₂ gas was used as a purge gas.

Process (1): The silicon precursor of Synthesis Example (vaporized in the stainless steel bubbler container) was transferred to the substrate for about 10 seconds by using N₂ gas supplied at a flow rate of 100 sccm, as a transfer gas, and adsorbed on the substrate.

Process (2): The unadsorbed silicon precursor was removed for about 30 seconds by using N₂ gas supplied at a flow rate of 2,000 sccm as a purge gas.

Process (3): A silicon oxide film was formed for about 10 seconds by using 02 gas supplied at a flow rate of 3,500 sccm and H₂ gas supplied at a flow rate of 1,200 sccm, as process gases.

Process (4): Reaction by-products and a residual reaction gas were removed for about 5 seconds by using N₂ gas supplied at a flow rate of 2,000 sccm, as a purge gas.

By repeating a plurality of cycles, one cycle being the processes (1) to (4), a silicon oxide film was formed to a certain thickness.

Table 1 below shows detailed deposition conditions of a silicon oxide film according to the Formation Example and a silicon oxide film according to the Comparative Example.

TABLE 1

| | | Formation | Comparative |
|---|---|---|---|
| | | Example | Example |
| Silicon Precursor | | (morpholino)tri- | bis(pyrrolidino)di- |
| | | methoxysilane | methoxysilane |
| Silicon Oxide Film | | ALD Window | ALD Window |
| Deposition Condition | | | |
| Substrate Temperature (° C.) | | 550, 600, 650, 700 | 550, 600, 650 |
| Silicon | Heating | 80 | 113 |
| Precursor | Temperature | | |
| | (° C.) | | |
| | Injection | 10 | 10 |
| | Time (sec.) | | |
| Purge Gas | Flow rate | 2,000 | 2,000 |
| | (sccm) | | |
| | Injection | 30 | 30 |
| | Time (sec.) | | |
| Reaction | Oxygen | 3,500 | 3,500 |
| Gas | Flow Rate | | |
| | (sccm) | | |
| | Hydrogen | 1,200 | 1,200 |
| | Flow Rate | | |
| | (sccm) | | |
| | Injection | 10 | 10 |
| | Time (sec.) | | |
| Purge Gas | Flow Rate | 2,000 | 2,000 |
| | (sccm) | | |
| | Injection | 5 | 5 |
| | Time (sec.) | | |
| Number of | Cycle | 140 | 100 |
| Depositions | | | |

With respect to the deposited silicon oxide film of each of the Formation Example and the Comparative Example, a thickness thereof was measured by using an ellipsometer, and the silicon oxide film formation and the component of a silicon oxide film were analyzed, which are shown in Table 2 and Table 3 below.

The thickness, growth speed, and refractive index of a deposited silicon oxide film through ellipsometer analysis are shown in Table 2. As the thickness of a thin film was very thin within about 100 Å, the refractive index was fixed to a value of 1.48.

The growth speed of the deposited silicon oxide film of the Formation Example had almost the same value in a substrate temperature range of 600° C. and 650° C. Accordingly, as a stable growth speed is obtained at a relatively high temperature, in the process of manufacturing an integrated circuit device, it may be seen that it is advantageous in terms of stability and mass productivity.

TABLE 2

| | | | Substrate | Thin Film | Growth | |
|---|---|---|---|---|---|---|
| | | Reaction | Temperature | Thickness | Speed | Refractive |
| | Silicon Precursor | Gas | (° C.) | (Å) | (Å/cycle) | Index |
| Formation | (morpholino)tri- | Oxygen | 550 | 112 | 0.80 | 1.48 |
| Example | methoxysilane | Gas and | 600 | 119 | 0.85 | 1.48 |
| | | Hydrogen | 650 | 120 | 0.86 | 1.48 |
| | | Gas | | | | |
| Comparative | bis(pyrrolidino)di- | Oxygen | 550 | 112 | 1.12 | 1.48 |
| Example | methoxysilane | Gas and | 600 | 112 | 1.12 | 1.48 |
| | | Hydrogen | 650 | 128 | 1.28 | 1.48 |
| | | Gas | | | | |

During ALD window evaluation according to the substrate temperature analyzed by using the X-ray photoelectron spectroscope, with respect to the composition of each of the deposited silicon oxide film of the Formation Example and the Comparative Example, the composition of a thin film (at %) is summarized in Table 3 below with a content amount value for each atom.

As a result, it may be seen that there was no C, N, fluorine (F), and Cl in the deposited silicon oxide film of the Formation Example, and that even when the substrate temperature increased, the silicon/oxygen ration in the silicon oxide film was almost constant.

TABLE 3

| | | Substrate | Composition of Thin Film | | | | | | |
|---|---|---|---|---|---|---|---|---|---|
| | | Temperature | (at %) | | | | | | Si/O |
| | Silicon Precursor | (° C.) | C | N | Si | O | F | Cl | Ratio |
| Formation | (morpholino)tri- | 550 | 0 | 0 | 35.1 | 64.9 | 0 | 0 | 0.54 |
| Example | methoxysilane | 600 | 0 | 0 | 34.9 | 65.1 | 0 | 0 | 0.54 |
| | | 650 | 0 | 0 | 34.7 | 65.3 | 0 | 0 | 0.53 |
| Comparative | bis(pyrrolidino)di- | 550 | 0.8 | 0 | 35.3 | 63.9 | 0 | 0 | 0.55 |
| Example | methoxysilane | 600 | 0 | 0 | 35.4 | 64.6 | 0 | 0 | 0.55 |
| | | 650 | 0 | 0 | 35.0 | 65.0 | 0 | 0 | 0.54 |

Furthermore, wet etching resistance analysis of the deposited silicon oxide film of each of the Formation Example and the Comparative Example was conducted. First etching and second etching (a total two times of etching) were performed, each for 10 seconds, by using dilute hydrofluoric acid (H₂O:HF=200:1) as an etchant. The thickness of a thin film after the first etching and the second etching was measured and shown in Table 4 below, and etch rates during the first etching and second etching are shown in Table 5 below.

As shown in Table 5 below, the etch rate of the deposited silicon oxide film of the Formation Example was about 1.8 Å/sec to about 2.4 Å/sec, which shows excellent wet etching resistance, and it may be seen that, as a substrate temperature increases, the wet etch rate of the deposited silicon oxide film of the Formation Example decreased.

TABLE 4

| | | | Thin Film Thickness (Å) | | |
|---|---|---|---|---|---|
| | | | | Thick- | Thick- |
| | | Substrate | | ness | ness |
| | | Temper- | Original | after | after |
| | Silicon | ature | Thick- | First | Second |
| | Precursor | (° C.) | ness | Etching | Etching |
| Formation | (morpholino)tri- | 600 | 118 | 81 | 57 |
| Example | methoxysilane | 650 | 127 | 96 | 78 |
| Compar- | bis(pyrrolidino)di- | 550 | 113 | 63 | 27 |
| ative | methoxysilane | 600 | 112 | 70 | 40 |
| Example | | 650 | 128 | 92 | 66 |

TABLE 5

| | | Substrate | Etch Rate (Å/sec) | |
|---|---|---|---|---|
| | Silicon | Temperature | At First | At Second |
| | Precursor | (° C.) | Etching | Etching |
| Formation | (morpholino)tri- | 600 | 3.72 | 2.41 |
| Example | methoxysilane | 650 | 3.11 | 1.84 |
| Comparative | bis(pyrrolidino)di- | 550 | 4.96 | 3.58 |
| Example | methoxysilane | 600 | 4.24 | 2.98 |
| | | 650 | 3.56 | 2.60 |

### (3) Evaluation Example

Deposition of a Silicon Oxide Film by a High Temperature ALD Process

In an atomic layer deposition apparatus configured as a typical vertical furnace using an ALD process, a thin film evaluation according to the feeding time of a reaction gas, by using (morpholino)trimethoxysilane (the compound of Synthesis Example), as a composition for depositing a silicon-containing film for forming a silicon oxide film. A substrate temperature was set to be 600° C., and the silicon precursor was filled in a stainless steel bubbler container and maintained at 80° C.

O₂ gas and H₂ gas were used as reaction gases, and N₂ gas was used as a purge gas.

Process (1): The silicon precursor of the Synthesis Example (vaporized in the stainless steel bubbler container) was transferred to the substrate for about 10 seconds by using N₂ gas supplied at a flow rate of 100 sccm, as a transfer gas, and adsorbed on the substrate.

Process (2): The unadsorbed silicon precursor was removed for about 30 seconds by using N₂ gas supplied at a flow rate of 2,000 sccm as a purge gas.

Process (3): A silicon oxide film was formed for about 10 seconds to about 20 seconds by using 02 gas supplied at a flow rate of 3,500 sccm and H₂ gas supplied at a flow rate of 1,200 sccm, as process gases.

Process (4): Reaction by-products and a residual reaction gas were removed for about 5 seconds by using N₂ gas supplied at a flow rate of 2,000 sccm, as a purge gas.

By repeating a plurality of cycles, one cycle being the processes (1) to (4), a silicon oxide film was formed to a certain thickness.

Table 6 below shows detailed deposition conditions of a silicon oxide film according to an Evaluation Example.

TABLE 6

| | |
|---|---|
| Silicon Precursor | (morpholino)trimethoxysilane |

| Silicon Oxide Film | | Evaluation according to Supply |
|---|---|---|
| Deposition Condition | | Time of Reaction Gas |
| Substrate Temperature (° C.) | | 600 |
| Silicon | Heating | 80 |
| Precursor | Temperature | |
| | (° C.) | |
| | Injection | 10 |
| | Time (sec.) | |
| Purge Gas | Flow Rate | 2,000 |
| | (sccm) | |
| | Injection | 30 |
| | Time (sec.) | |
| Reaction | Oxygen | 3,500 |
| Gas | Flow Rate | |
| | (sccm) | |
| | Hydrogen | 1200 |
| | Flow Rate | |
| | (sccm) | |
| | Injection | 10-20 |
| | Time (sec.) | |
| Purge Gas | Flow Rate | 2,000 |
| | (sccm) | |
| | Injection | 5 |
| | Time (sec.) | |
| Number of | Cycle | 140 |
| Depositions | | |

The thickness of the deposited silicon oxide film of the Evaluation Example was measured by using an ellipsometer. The thickness, growth speed, and refractive index of the deposited silicon oxide film through ellipsometer analysis are shown in Table 7 below. As the thickness of a thin film was very thin within about 100 Å, the refractive index was fixed to a value of 1.48.

It may be seen that the growth speed of a thin film is at a similar level regardless of the feeding time of a reaction gas. Such a result may be interpreted as meaning that when a certain amount or more of a reaction gas is supplied, a constant thin film growth speed may be obtained. Accordingly, the silicon oxide film of the Evaluation Example had the characteristics that thickness control of a thin film was easy even in a high temperature process (e.g., 600° C.).

TABLE 7

| | | | Thin | | |
|---|---|---|---|---|---|
| | Substrate | Feeding | Film | Growth | |
| | Temperature | Time | Thickness | Speed | Refractive |
| Evaluation | (° C.) | (sec.) | (Å) | (Å/cycle) | Index |
| Evaluation | 600 | 10 | 119 | 0.85 | 1.48 |
| According | | | | | |
| to Feeding | | 20 | 123 | 0.88 | 1.48 |
| Time of | | | | | |
| Reaction Gas | | | | | |

### (4) Properties of a Silicon Compound

The silicon compound according to embodiments may provide high thermal stability and excellent reactivity when a silicon precursor for forming a silicon-containing film is used in a relatively high process temperature range of 550° C. to 650° C.

Furthermore, when forming a silicon-containing film using a silicon compound according to embodiments, a high purity silicon-containing film that does not include a Cl atom may be provided, and the obtained silicon-containing film may provide excellent physical properties and electrical properties.

Ultimately, by forming a silicon-containing film using a silicon compound according to embodiments, a method of manufacturing an integrated circuit device may help improve electrical properties and product productivity.

By way of summation and review, raw material compounds to form a silicon containing film may provide a stable deposition process, may be easy to handle, and may have excellent thin film properties and excellent etch resistance properties during forming of the silicon containing film. A silicon compound according to an embodiment may be advantageous in terms of stability and mass productivity of a semiconductor manufacturing process.

One or more embodiments may provide a silicon compound used to form a silicon containing film.

One or more embodiments may provide a silicon compound which may form a thin film having a uniform thickness and may be easily handled under a relatively high process temperature condition, and may be usefully usable as a raw material compound to form a silicon containing film.

One or more embodiments may provide a process of forming a silicon containing compound having excellent thin film properties and excellent etch resistance properties, by using a silicon compound according to an embodiment.

One or more embodiments may provide a method of manufacturing an integrated circuit device which may help improve electrical properties and product productivity, by forming a silicon containing film having excellent quality by using a silicon compound that can provide excellent stability and mass productivity of a manufacturing process.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A silicon compound represented by Chemical Formula (1): 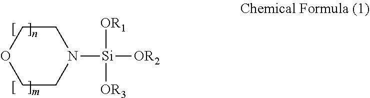
wherein, in Chemical Formula (1),
R₁ to R₃ are each independently a C1-C4 alkyl group, and
n and m are each independently an integer of 0 to 3.

2. The silicon compound as claimed in claim 1, wherein, in Chemical Formula (1):
R₁ to R₃ are each independently a methyl group or an ethyl group, and
n and m are each independently an integer of 0 to 2.

3. A composition for depositing a silicon-containing film, the composition comprising the silicon compound according as claimed in claim 1.

4. A process of forming a silicon-containing film, the process comprising:
forming a silicon compound adsorption layer on a substrate having a temperature of 550° C. or more, by supplying a silicon compound represented by Chemical Formula (1); and
supplying a reaction gas onto the silicon compound adsorption layer, 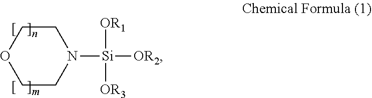
wherein, in Chemical Formula (1),
R₁ to R₃ are each independently a C1-C4 alkyl group, and
n and m are each independently an integer of 0 to 3.

5. The process as claimed in claim 4, wherein, in Chemical Formula (1):
R₁ to R₃ are each independently a methyl group or an ethyl group, and
n and m are each independently an integer of 0 to 2.

6. The process as claimed in claim 4, wherein the silicon compound represented by Chemical Formula (1) is Compound (1), Compound (2), or Compound (3),

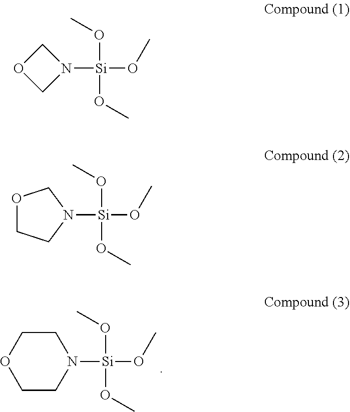

7. The process as claimed in claim 4, wherein the silicon-containing film does not include a chlorine atom.

8. The process as claimed in claim 4, wherein the reaction gas includes oxygen, ozone, oxygen plasma, hydrogen, or hydrogen plasma.

9. The process as claimed in claim 4, wherein the silicon compound has a substantially constant thin film growth speed in a temperature range of 600° C. to 650° C.

10. The process as claimed in claim 4, wherein:
forming the silicon compound adsorption layer and supplying the reaction gas constitute a first cycle, and
a silicon oxide film is formed on the substrate by repeating the first cycle multiple times.

11. A method of manufacturing an integrated circuit device, the method comprising:
forming a silicon oxide film on a substrate having a temperature of 550° C. or more, by using a silicon compound represented by Chemical Formula (1): 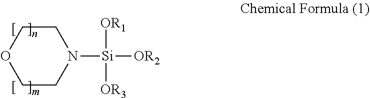
wherein, in Chemical Formula (1),
R₁ to R₃ are each independently a C1-C4 alkyl group, and
n and m are each independently an integer of 0 to 3.

12. The method as claimed in claim 11, wherein, in Chemical Formula (1):
R₁ to R₃ are each independently a methyl group or an ethyl group, and
n and m are each independently an integer of 0 to 2.

13. The method as claimed in claim 11, wherein forming the silicon oxide film includes:
forming a silicon compound adsorption layer of the silicon compound represented by Chemical Formula (1), on the substrate in a reaction space, in a state in which a temperature of the substrate is 550° C. to 650° C.; and
supplying a reaction gas onto the silicon compound adsorption layer.

14-20. (canceled)
